(19) United States
(12) Patent Application Publication
(10) Pub. No.: US 2011/0042704 A1
(43) Pub. Date: Feb. 24, 2011

(54) METHOD OF COATING SULFIDE PHOSPHOR AND LIGHT EMITTING DEVICE EMPLOYING COATED SULFIDE PHOSPHOR

(75) Inventors: Kyung Nam KIM, Ansan-si (KR); Tomizo MATSUOKA, Ansan-si (KR); Sang Mi PARK, Ansan-si (KR); Hyung Keun LEE, Ansan-si (KR); Mi Youn Chang, Ansan-si (KR)

Correspondence Address: H.C. PARK & ASSOCIATES, PLC, 8500 LEESBURG PIKE, SUITE 7500, VIENNA, VA, 22182, US

(73) Assignee: SEOUL SEMICONDUCTOR CO., LTD., Seoul (KR)

(21) Appl. No.: 12/917,010

(22) Filed: Nov. 1, 2010

Related U.S. Application Data
(62) Division of application No. 12/058,453, filed on Mar. 28, 2008.

(30) Foreign Application Priority Data
Mar. 30, 2007 (KR) 10-2007-0032023

(51) Int. Cl. H01L 33/44

(52) U.S. Cl. 257/98; 257/E33.061

(57) ABSTRACT

A method of coating phosphor powder with a composite oxide, and a light emitting device that employs the phosphor powder coated with the composite oxide are disclosed. The method includes mixing a silicon oxide precursor and a precursor of another oxide in water and alcohol to form a primary coating layer on a sulfide phosphor through a sol-gel reaction, heat treating the primary coating layer to form a composite oxide layer of the silicon oxide and the other oxide from the primary coating layer. The method improves moisture stability of the sulfide phosphor compared to a sulfide phosphor coated with a single silicon oxide film.

### CROSS REFERENCE TO RELATED APPLICATIONS

This application is a divisional of U.S. patent application Ser. No. 12/058,453, filed on Mar. 28, 2008, and claims priority from and the benefit of Korean Patent Application No. 10-2007-0032023, filed on Mar. 30, 2007, which are both hereby incorporated by reference for all purposes as if fully set forth herein.

### BACKGROUND OF THE INVENTION

### Field of the Invention

The present invention relates to a method of coating phosphor powder and a light emitting device employing the coated phosphor powder. More particularly, the present invention relates to a method of coating phosphor powder with a composite oxide, and a light emitting device that employs the phosphor powder coated with the composite oxide.

### DISCUSSION OF THE BACKGROUND

Currently, Light Emitting Diode (LED) technology is being advanced to manufacture lightweight, compact and small LEDs while ensuring extended service life and reduced energy consumption. The LEDs are widely used for a backlight source of various display devices including mobile phones and the like. A light emitting device mounted with the LED provides white light exhibiting high color-rendering properties and is thus expected to be applied to general lighting instead of a white light source such as fluorescent lamps.

Meanwhile, various methods have been proposed to realize white light using the LEDs. In a method generally used in the art, an InGaN-based LED emitting blue light in the wavelength range of 430 nm˜470 nm is combined with phosphors capable of converting the blue light into longer wavelengths of light to realize white light. For example, white light can be realized by a combination of the blue LED and yellow phosphors excited by the blue LED and emitting yellow light or by a combination of the blue LED, green phosphors, and red phosphors.

However, a white LED obtained by the combination of the blue LED and the yellow phosphors has difficulty in achieving a color-rendering index of 85 or more, and cannot realize approximately natural color due to low color purity after light penetrates a color filter when used as a backlight source for a Liquid Crystal Display (LCD). Conversely, a white LED obtained by the combination of the blue LED and the green and red phosphors can provide high color-rendering properties and realize approximately natural color images when used as the backlight source for the LCD. This is because the white LED of this combination exhibits a very high compatibility with the color filter and thus provides light of high color purity after penetrating the color filter. Accordingly, light emitting devices capable of realizing white light with the blue LED and the green and red phosphors are suitable backlight sources for LCDs.

Representative examples of the green phosphors applicable to the white light emitting device include orthosilicate and thiogallate phosphors, both of which exhibit excellent excitation efficiency. However, since sulfide-based thiogallate phosphors such as (Ca,Sr,Ba)(Al,In,Ga)₂S₄:Eu phosphors have poor chemical stability with respect to moisture, the initial optical properties of thiogallate phosphors tend to deteriorate quickly.

Meanwhile, examples of the red phosphors include sulfide-based phosphors such as (Ca,Sr)S:Eu and CaS:Eu phosphors, and nitride-based phosphors, such as (Ca,Sr,Ba)₂Si₅N₈:Eu, CaAlSiN₃:Eu,Ce, (Ca,Sr,Ba)Si₇N₁₀:Eu, and CaSiN₂:Eu phosphors, which have been newly developed in recent years.

Nitride-based phosphors have excellent chemical stability, but their emission spectrum substantially overlaps a green emission spectrum, which is close to the emission spectrum of the nitride-based phosphor, due to a considerably wide full width at half maximum in the range of about 90 nm˜110 nm. As such, since the nitride phosphor-based white light emitting device provides light exhibiting lower color purity after penetrating the color filter, there is a difficulty in applying the nitride phosphor-based white light emitting device to the backlight source for the LCD.

The sulfide-based phosphor exhibits excellent efficiency of excitation by blue light and has a very narrow full width at half maximum in the range of about 60 nm˜70 nm, which means that it does not substantially influence an adjacent spectrum. Accordingly, when used as the backlight source for the LCD, the sulfide-based phosphor exhibits high color reproducibility. However, since the sulfide-based phosphor has a very low stability with respect to moisture, it is difficult to apply the sulfide-based phosphor to the light emitting device.

When employing sulfide phosphors, such as (Ca,Sr,Ba)(Al,In,Ga)₂S₄:Eu, (Ca,Sr)S:Eu, and the like, the emission spectrum of the light emitting device undergoes rapid changes due to environmental factors, such as humidity and temperature, which cause brightness reduction and extreme variation in chromaticity coordinates. In particular, (Ca,Sr,Ba)(Al,In,Ga)₂S₄:Eu phosphors and (Ca,Sr)S:Eu phosphors react with moisture and are converted to carbonates or sulfates, finally resulting in failure of their inherent luminescence properties.

To solve such problems of the sulfide phosphor, a technique of coating the surface of the sulfide phosphor with a silicon oxide film is proposed. For example, Korean Patent Laid-open Publication No. 10-2006-0079746 discloses a method of coating a sulfide phosphor with a silicon oxide film using a silane-based modifier to improve the chemical stability of the sulfide phosphor.

However, even when coated with the silicon oxide film, the sulfide phosphor does not have sufficient moisture stability. Therefore, there is still a need for a method of forming a coating layer which can improve the chemical stability of the sulfide phosphor.

### SUMMARY OF THE INVENTION

The present invention is conceived to solve the problems of the conventional techniques as described above, and it is an aspect of the present invention to provide a method of coating a sulfide phosphor with a composite oxide layer capable of providing better chemical stability than the silicon oxide film.

It is another aspect of the present invention to provide a light emitting device employing a sulfide phosphor which exhibits high chemical stability with respect to moisture.

To achieve the features of the present invention, the present invention provides a method of coating a sulfide phosphor and a light emitting device.

The method includes mixing a silicon oxide precursor and a precursor of another oxide in water and alcohol to form a primary coating layer on a sulfide phosphor through a sol-gel reaction; heat treating the primary coating layer to form a composite oxide layer of the silicon oxide and the other oxide from the primary coating layer.

The sol-gel reaction may be conducted by hydrolysis and condensation polymerization of the silicon oxide precursor and/or the other oxide precursor, during which the primary coating layer is formed on the sulfide phosphor. To promote the hydrolysis and condensation polymerization, a pH of the mixed solution may be adjusted. For this purpose, a proper amount of ammonia solution may be added to the mixed solution. Further, to promote the hydrolysis and condensation polymerization, the mixed solution of water, alcohol, and the precursors may be heated. For example, if the alcohol is ethanol, the mixed solution may be heated to 75° C.˜78° C., which is lower than the boiling point of ethanol.

The method may further include separating the sulfide phosphor having the primary coating layer from the mixed solution of water, alcohol, and the precursors, followed by drying at 100° C.˜150° C. for 1 to 5 hours in an oven and the like to remove water and alcohol from the primary coating layer.

The sulfide phosphor may comprise a red phosphor expressed by (Ca, Sr)S:Eu or a thiogallate phosphor exhibiting low chemical stability with respect to moisture.

In accordance with one aspect of the present invention, a method of coating a sulfide phosphor includes mixing water, alcohol, a silicon oxide precursor of TEOS or TMOS, a boron oxide precursor of boron triethoxide, and a sulfide phosphor to form a primary coating layer on a surface of the sulfide phosphor through reaction of the phosphors. Then, the phosphor having the primary coating layer formed on the surface thereof is dried, followed by heat treatment at a temperature of 200° C.˜600° C., thereby forming a composite oxide of SiO₂ and B₂O₃ from the primary coating layer.

Water and alcohol may be mixed in amounts of 0.5 cc˜50 cc and 20 cc˜300 cc with respect to 3 g of sulfide phosphor, respectively, and the silicon oxide precursor and the boron oxide precursor may be mixed in a ratio of 0.1 wt %˜10 wt % with respect to a total weight of sulfide phosphor.

The boron oxide precursor may be mixed in a ratio of 1 wt %˜25 wt % with respect to a total weight of the precursors, preferably in a ratio of 2 wt %˜15 wt %, and more preferably in a ratio of 5 wt %˜10 wt %.

In accordance with another aspect of the present invention, a method of coating a sulfide phosphor includes mixing water, alcohol, a silicon oxide precursor of TEOS or TMOS, a titanium oxide precursor of Ti-isopropoxide, and a sulfide phosphor to form a primary coating layer on a surface of the sulfide phosphor through reaction of the precursors. Then, the phosphor having the primary coating layer formed on the surface thereof is dried, followed by heat treatment at a temperature of 200° C.˜600° C., thereby forming a composite oxide of SiO₂ and TiO₂ from the primary coating layer.

Water and alcohol may be mixed in amounts of 0.5 cc˜50 cc and 20 cc˜300 cc with respect to 3 g of sulfide phosphor, respectively, and the silicon oxide precursor and the titanium oxide precursor may be mixed in a ratio of 0.1%˜10 wt % with respect to a total weight of the sulfide phosphor.

The titanium oxide precursor may be mixed in a ratio of 5 wt %˜50 wt % with respect to a total weight of the precursors. If the titanium oxide precursor is mixed in a ratio less than 5 wt %, the sulfide phosphor fails to have improved chemical stability with respect to moisture. If the titanium oxide precursor is mixed in a ratio greater than 50 wt %, the sulfide phosphor has a lower chemical stability with respect to moisture than the silicon oxide film. More preferably, the titanium oxide precursor is mixed in a ratio of 10 wt %˜30 wt % with respect to the total weight of the precursors.

In accordance with a further aspect of the present invention, a method of coating a sulfide phosphor includes mixing water, alcohol, a silicon oxide precursor of TEOS or TMOS, a zinc oxide precursor selected from one of the group consisting of ZnCl₂, Zn(NO₃)₂, Zn-diethoxide, Zn-acetylacetonate and Zn-acetate, and a sulfide phosphor to form a primary coating layer on a surface of the sulfide phosphor through reaction of the precursors. Then, the phosphor having the primary coating layer formed on the surface thereof is dried, followed by heat treatment at a temperature of 200° C.˜600° C., thereby forming a composite oxide of SiO₂ and ZnO from the primary coating layer.

Water and alcohol may be mixed in amounts of 0.5 cc˜50 cc and 20 cc˜300 cc with respect to 3 g of sulfide phosphor, respectively, and the silicon oxide precursor and the zinc oxide precursor may be mixed in a ratio of 0.1 wt %˜10 wt % with respect to a total weight of the sulfide phosphor.

The zinc oxide precursor may be mixed in a ratio of 5 wt %˜35 wt % with respect to a total weight of the precursors. If the zinc oxide precursor is mixed in a ratio less than 5 wt %, the sulfide phosphor fails to have improved chemical stability with respect to moisture. If the zinc oxide precursor is mixed in a ratio greater than 35 wt %, the sulfide phosphor has a lower chemical stability with respect to moisture than the silicon oxide film. More preferably, the zinc oxide precursor is mixed in a ratio of 10 wt %˜25 wt % with respect to the total weight of the precursors.

In accordance with yet another aspect of the present invention, a light emitting device includes a light emitting diode and a sulfide phosphor performing wavelength conversion upon light emitted from the light emitting diode. The sulfide phosphor is coated with a composite oxide layer.

By employing the sulfide phosphor coated with the composite oxide layer, it is possible to improve the chemical stability of the sulfide phosphor with respect to moisture and to improve reliability of the light emitting device. The sulfide phosphor can be coated with the composite oxide layer by any one of the methods described above.

The light emitting device may further include a phosphor performing wavelength conversion upon light emitted from the light emitting diode into light having a wavelength in the range of 500 nm˜600 nm. Examples of the phosphor include, but are not limited to, an orthosilicate phosphor and a thiogallate phosphor.

The light emitting device may emit blue light. The phosphor performing the wavelength conversion upon light into the light in the range of 500 nm˜600 nm may comprise an orthosilicate phosphor, and the sulfide phosphor may comprise a red phosphor expressed by general formula of (Ca, Sr)S:Eu. With this configuration, the light emitting device has improved reliability.

### BRIEF DESCRIPTION OF THE DRAWINGS

The above and other features and advantages of the present invention will become apparent from the following description of exemplary embodiments given in conjunction with the accompanying drawings, in which:

FIG. 1 is a flow chart illustrating a method of coating a sulfide phosphor according to one embodiment of the present invention;

FIG. 2 is a cross-sectional view illustrating a composite oxide layer coated on the surface of the sulfide phosphor by the method of FIG. 1;

FIG. 3 is a graph depicting moisture stability of a sulfide phosphor having a composite oxide layer coated thereon according to Example 1 of the present invention;

FIG. 4 is a graph depicting moisture stability of a sulfide phosphor having a composite oxide layer coated thereon according to Example 2 of the present invention;

FIG. 5 is a graph depicting moisture stability of a sulfide phosphor having a composite oxide layer coated thereon according to Example 3 of the present invention; and

FIG. 6 is a cross-sectional view of a light emitting device according to one embodiment of the present invention.

### DETAILED DESCRIPTION OF THE INVENTION

Exemplary embodiments of the present invention will be described in detail with reference to the accompanying drawings.

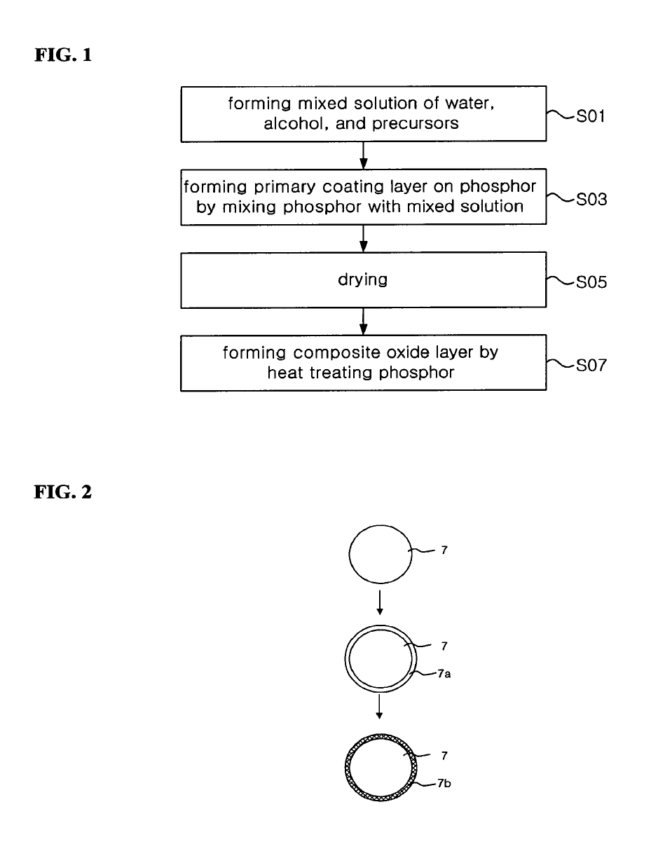

FIG. 1 is a flow chart illustrating a method of coating a sulfide phosphor according to one embodiment of the present invention, and FIG. 2 is a cross-sectional view illustrating a composite oxide layer coated on the surface of the sulfide phosphor by the method of FIG. 1.

Referring to FIGS. 1 and 2, water, alcohol, a silicon oxide precursor, and a precursor of another oxide are mixed to prepare a mixed solution (S01). Examples of alcohol include, but are not limited to, methanol, ethanol, isopropanol, and butanol. Particularly, ethanol is preferably employed as the alcohol since ethanol can be easily obtained and is inexpensive.

As the silicon oxide precursor, an organic compound such as tetraethyl orthosilicate (TEOS) and tetramethyl orthosilicate (TMOS) may be used. TEOS or TMOS is dissolved in alcohol and experiences a sol-gel reaction by hydrolysis and condensation polymerization. In this embodiment, TEOS or TMOS can be used as stock solution without any dilution. Alternatively, TEOS or TMOS can be used after dilution with alcohol such as dehydrated ethanol for measurement convenience and adjustment of a hydrolysis speed.

Further, examples of the precursor of the other oxide include, but are not limited to, a boron oxide precursor, a titanium oxide precursor, and a zinc oxide precursor. An exemplary organic compound of the boron oxide precursor may include boron triethoxide, which can be used as stock solution without any dilution or can be used after dilution with alcohol such as dehydrated ethanol. An exemplary organic compound of the titanium oxide precursor may include Ti-isopropoxide, which can be used as stock solution or after dilution with alcohol such as dehydrated ethanol. Further, examples of the zinc oxide precursor include, but are not limited to, ZnCl₂, Zn(NO₃)₂, Zn-diethoxide, Zn-acetylacetonate, Zn-acetate, and the like. Here, ZnCl₂ can be used after being diluted with dilute hydrochloric solution, and other organic compounds can be used after being diluted with alcohol.

With respect to 3 g of a phosphor as a coating target, water and alcohol may be added in the range of 0.5 cc˜50 cc and 20 cc˜300 cc, respectively. If less than 0.5 cc of water is added, the hydrolysis of the precursors does not sufficiently occur, making formation of the primary coating layer difficult. Conversely, if greater than 50 cc of water is added, water actively interacts with the sulfide phosphor, causing degradation of luminescence properties of the sulfide phosphor. When less than 20 cc or greater than 300 cc of alcohol is added, the precursors experience slow hydrolysis and condensation polymerization.

On the other hand, a total amount of the precursors in the mixed solution, that is, a total amount of the silicon oxide precursor and the other oxide precursor, may be in the range of 0.1 wt %˜10 wt % with respect to the weight of a phosphor as the coating target. If the total amount of the precursors added is less than 0.1 wt %, uniform primary coating layer cannot be achieved due to lack of the precursors. If the total amount of precursors added is greater than 10 wt %, formation of the primary coating layer fails and precursor consumption is excessive.

A proper amount of the precursors can be different according to the particle size of the phosphor. For example, when using (Ca, Sr)S:Eu phosphor powder having an average particle size of 7 μm˜8 μm, about 3 wt % of precursors achieves optimal formation of the primary coating layer. On the other hand, when using phosphor powder having an average particle size of 2 μm˜3 μm, about 10 wt % of precursors achieves optimal formation of the primary coating layer due to an increase of surface area.

After preparing the mixed solution, a phosphor 7 (see FIG. 7) prepared as the coating target is mixed with the mixed solution to form the primary coating layer on the surface of the phosphor (S03). The phosphor 7 is mixed in a powdery phase, and a single particle of the phosphor is shown in the figure.

The organic compound precursors undergo hydrolysis and condensation polymerization in the mixed solution to which water is added, so that the sol-gel reaction of the precursors occurs. In this process, compounds generated by reaction of the precursors are attached to the surface of the phosphor, thereby forming a primary coating layer 7a (FIG. 2).

Various methods can be adopted to adjust the hydrolysis and condensation polymerization. For example, ammonia solution may be added to the mixed solution to promote the hydrolysis and condensation polymerization. Here, the ammonia solution promotes the hydrolysis and condensation polymerization by adjusting the pH of the mixed solution. For example, 5 vol. % of ammonia solution to the total volume of water and alcohol is added to the mixed solution and is then uniformly mixed therein for 1 hour˜20 hours. Further, the mixed solution may be heated to promote the hydrolysis and condensation polymerization. For example, when ethanol is employed as the alcohol, the mixed solution is heated to 75° C.˜78° C., which is lower than the boiling point of ethanol, and is then stirred for about 0.5 hours, thereby forming the primary coating layer.

Next, the phosphor 7 having the primary coating layer 7a is dried (S05). For this purpose, the phosphor 7 having the primary coating layer 7a is separated from the mixed solution, followed by drying at a temperature of, for example, 100°˜150° C., thereby removing water and alcohol from the primary coating layer.

Next, the dried phosphor 7 is heat treated to form a composite oxide layer 7b from the primary coating layer (S07). For example, the phosphor 7 having the primary coating layer 7a is heat treated at a temperature of 200° C.˜600° C. for about 1 hour˜24 hours, thereby forming a composite oxide layer of the silicon oxide and the other oxide. When heat treatment is performed below 200° C., organics in the primary coating layer 7a can be removed, thereby failing to form the oxide layer. Conversely, when heat treatment is performed above 600° C., the properties of the sulfide phosphor can be degraded.

The heat treatment can be performed in an oxygen containing atmosphere or in air.

According to this embodiment, the method of coating the composite oxide layer 7b on the surface of the sulfide phosphor 7 can ensure the chemical stability of the sulfide phosphor with respect to moisture.

Meanwhile, the mixed solution and the phosphor are mixed after preparing the mixed solution in this embodiment, but the present invention is not limited to this sequence. For example, water, alcohol, and the precursors can be mixed along with the phosphor. Alternatively, water can be added after mixing the phosphor, alcohol and the precursors. Such a mixing sequence can be selected according to reaction speed of hydrolysis and condensation polymerization. For example, if the speed of hydrolysis and condensation polymerization of the precursors is relatively slow in the mixed solution containing water, the phosphor can be added later. Conversely, if the speed of hydrolysis and condensation polymerization of the precursors is relatively fast, the phosphor is added together with other components or water is added later.

### Example 1

TEOS was used as a silicon oxide precursor and boron triethoxide was used as a boron oxide precursor. TEOS was diluted in a ratio of 1 wt % (with respect to the weight of phosphor) per 1 cc of anhydrous ethanol, and boron triethoxide was diluted in a ratio of 0.25 wt % (with respect to the weight of phosphor) per 1 cc of anhydrous ethanol.

A total weight ratio of the TEOS and boron triethoxide precursors was fixed to 3 wt % with respect to the weight of (Ca, Sr)S:Eu phosphor. An oxide layer was formed on the surface of 3 g of sulfide phosphor by changing a weight ratio of the boron triethoxide precursor with respect to the total weight of the precursors while maintaining other conditions. Then, moisture stability of the phosphor coated with the oxide layer was tested.

To determine a relationship between the moisture stability of the sulfide phosphor and the weight ratio of the boron triethoxide precursor, after exposing the phosphor to 100° C. steam for 10 hours, luminescence of the phosphor, i.e. PL, was measured and compared to PL before exposure to obtain a degradation ratio of PL, results of which are shown in FIG. 3.

As can be appreciated from FIG. 3, the phosphor having a composite oxide layer formed with the boron oxide precursor had an approximately lower degradation ratio of PL than the phosphor having a single silicon oxide formed thereon. However, when greater than 25 wt % of the boron oxide precursor with respect to the total weight of the precursors was added, the chemical stability of the phosphor with respect to moisture was further degraded than that of the phosphor having the silicon oxide film. On the other hand, when the boron oxide precursor was added in the range of 2 wt %˜15 wt % with respect to the total weight of the precursors, the chemical stability of the phosphor with respect to moisture was considerably improved compared to that of the phosphor having the silicon oxide film. In particular, when the boron oxide precursor was added in a ratio of 5 wt %˜10 wt %, the chemical stability was excellent.

### Example 2

TEOS was used as a silicon oxide precursor and TIP was used as a titanium oxide precursor. Both TEOS and TIP were diluted in a ratio of 1 wt % (with respect to the weight of phosphor) per 1 cc of anhydrous ethanol.

A total weight ratio of TEOS and TIP was fixed to 3 wt % with respect to the weight of (Ca, Sr)S:Eu phosphor. An oxide layer was formed on the surface of 3 g of sulfide phosphor by changing a weight ratio of TIP with respect to the total weight of the precursors while maintaining other conditions. Then, the moisture stability of the phosphor was tested.

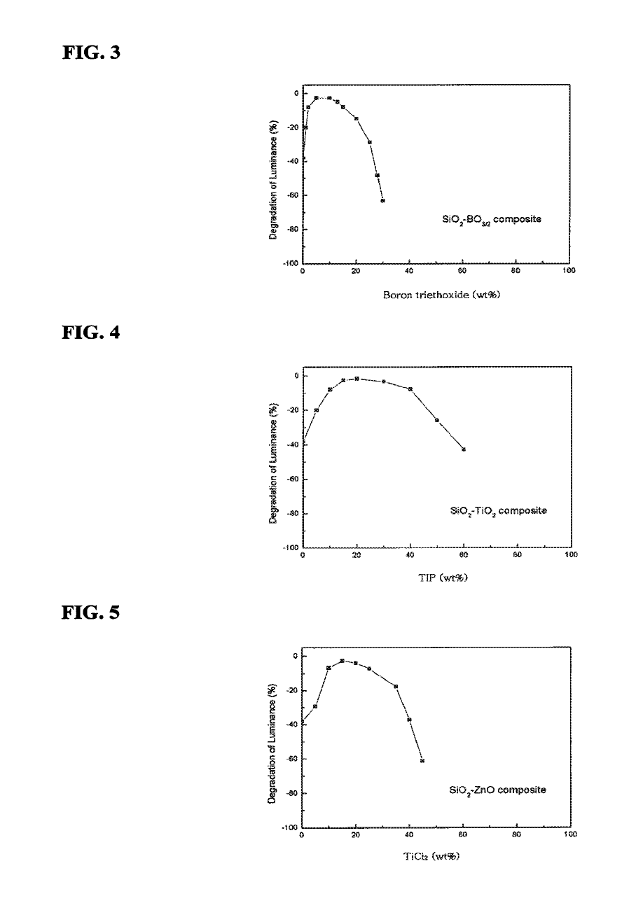

To determine a relationship between the moisture stability of the sulfide phosphor and the weight ratio of TIP, after exposing the phosphor to 100° C. steam for 10 hours, luminescence of the phosphor, i.e. PL, was measured and compared to PL before exposure to obtain a degradation ratio of PL, results of which are shown in FIG. 4.

As can be appreciated from FIG. 4, the phosphor having a composite oxide layer formed with the TIP precursor had an approximately lower degradation ratio of PL than the phosphor having a single silicon oxide formed thereon. However, when greater than 50 wt % of the TIP precursor with respect to the total weight of the precursors was added, the chemical stability of the phosphor with respect to moisture was further degraded than that of the phosphor having the silicon oxide film. On the other hand, when the TIP precursor was added in the range of 10 wt %˜40 wt % with respect to the total weight of the precursors, the chemical stability of the phosphor with respect to moisture was considerably improved compared to that of the phosphor having the silicon oxide film.

### Example 3

TEOS was used as a silicon oxide precursor and ZnCl₂ was used as a zinc oxide precursor. TEOS was diluted in a ratio of 1 wt % (with respect to the weight of phosphor) per 1 cc of anhydrous ethanol, and ZnCl₂ was diluted in a ratio of 0.25 wt % (with respect to the weight of phosphor) per 1 cc of hydrochloric solution.

A total weight ratio of TEOS and ZnCl₂ was fixed to 3 wt % with respect to the weight of (Ca, Sr)S:Eu phosphor. An oxide layer was formed on the surface of 3 g of sulfide phosphor by changing a weight ratio of ZnCl₂ with respect to the total weight of the precursors while maintaining other conditions. Then, the moisture stability of the phosphor was tested.

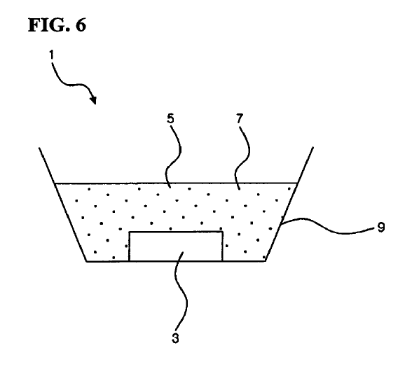

To determine a relationship between the moisture stability of the sulfide phosphor and the weight ratio of ZnCl₂, after exposing the phosphor to 100° C. steam for 10 hours, luminescence of the phosphor, i.e. PL, was measured and compared to PL before exposure to obtain a degradation ratio of PL, results of which are shown in FIG. 5.

As can be appreciated from FIG. 5, the phosphor having a composite oxide layer formed with the ZnCl₂ precursor had an approximately lower degradation ratio of PL than the phosphor having a single silicon oxide formed thereon. However, when greater than 40 wt % ZnCl₂ with respect to the total weight of the precursors was added, the chemical stability of the phosphor with respect to moisture was further degraded than that of the phosphor having the silicon oxide film. On the other hand, when ZnCl₂ was added in the range of 10 wt %˜25 wt % with respect to the total weight of the precursors, the chemical stability of the phosphor with respect to moisture was considerably improved compared to that of the phosphor having the silicon oxide film.

FIG. 6 is a cross-sectional view of a light emitting device according to one embodiment of the present invention.

Referring to FIG. 6, the light emitting device 1 includes a light emitting diode 3 and a sulfide phosphor 7. The light emitting diode 3 is an (Al, In, Ga)N-based light emitting diode and emits ultraviolet rays or blue light in the wavelength range of 420 nm˜290 nm.

Generally, the light emitting diode 3 has two electrodes connected to an external power source. The electrodes may be located on the same side of the light emitting diode 3 or on opposite sides thereof. The electrodes may be electrically connected to lead terminals (not shown) of a lead frame or a printed circuit board via an adhesive or bonding wires (not shown).

The light emitting diode 3 may be disposed inside a reflection cup 9. The reflection cup 9 reflects light emitted from the light emitting diode 3 at a desired viewing angle, increasing brightness of light in a predetermined viewing angle range. Hence, the reflection cup 9 has a predetermined slope formed according to the desired viewing angle.

The sulfide phosphor 7 is located above the light emitting diode 3 and converts a portion of light emitted from the light emitting diode 3 into red light. At this time, the sulfide phosphor 7 may be distributed in an encapsulating material 5. The encapsulating material 5 covers the light emitting diode 3 to protect the light emitting diode 3 from surroundings such as moisture or external force. The encapsulating material 5 can be formed by curing a thermosetting resin such as epoxy or silicone and can be located inside the reflection cup 9 as shown in FIG. 6.

The phosphor 7 may be distributed in the encapsulating material 5 by mixing the phosphor 7 with the thermosetting resin and curing the thermosetting resin. Alternatively, the phosphor 7 may be distributed in the encapsulating material 5 by potting the thermosetting resin, dotting the phosphor 7 on the thermosetting resin, and then curing the thermosetting resin.

The surface of the phosphor 7 is coated with a composite oxide layer, which can be coated by the sulfide phosphor coating method as described above. Examples of the composite oxide layer include, but are not limited to, boron oxide, titanium oxide, and zinc oxide.

The light emitting device 1 may further include a green phosphor in addition to the phosphor 7. Examples of the green phosphor include, but are not limited to, an orthosilicate phosphor and a thiogallate phosphor. The orthosilicate phosphor is preferred due to its excellent chemical stability. The surface of the thiogallate phosphor is preferably coated with the composite oxide layer described above.

The light emitting device 1 can realize white light by means of the blue light emitting diode 3 and the green phosphor and sulfide phosphor 7. The light emitting device 1 has excellent color reproducibility and color purity, and thus can be applied to a backlight source for LCDs.

When the light emitting diode 3 emits ultraviolet rays, the light emitting device 1 may further include a blue phosphor capable of converting ultraviolet rays into blue light.

As apparent from the above description, according to exemplary embodiments of the present invention, the method of coating a sulfide phosphor with a composite oxide layer improves moisture stability of the sulfide phosphor. Accordingly, the sulfide phosphor coated with the composite oxide layer can be suitably applied to a backlight source for LCDs, thereby providing a white light emitting device having improved reliability. Furthermore, since the composite oxide layer is coated on the surface of the sulfide phosphor via a sol-gel reaction, it is possible to coat the sulfide phosphor at low cost and in large amounts by a simple process.

Although various exemplary embodiments have been described with reference to the accompanying drawings, the present invention is not limited to the embodiments and the drawings. It should be understood that various modifications and changes can be made by those skilled in the art without departing from the spirit and scope of the present invention as defined by the accompanying claims.

What is claimed is:

1. A light emitting device, comprising:
a light emitting diode; and
a sulfide phosphor coated with a composite oxide layer, the sulfide phosphor to convert light emitted from the light emitting diode to a different wavelength.

2. The light emitting device of claim 1, wherein the composite oxide layer comprises a silicon oxide and an oxide, the oxide being different than the silicon oxide.

3. The light emitting device of claim 1, further comprising a phosphor disposed on the light emitting diode, the phosphor to convert light emitted from the light emitting diode to a wavelength ranging from 500 nm to 600 nm.

4. The light emitting device of claim 3, wherein the light emitting device emits blue light, the phosphor comprises an orthosilicate phosphor, and the sulfide phosphor comprises a red phosphor having a general formula of (Ca, Sr)S:Eu.

5. The light emitting device of claim 2, wherein the oxide is selected from the group consisting of B₂O₃, TiO₂, and ZnO.

6. The light emitting device of claim 5, wherein the oxide is B₂O₃ and ranges from 5 wt % to 10 wt % of the composite oxide layer.

7. The light emitting device of the claim 5, wherein the oxide is TiO₂ and ranges from 10 wt % to 40 wt % of the composite oxide layer.

8. The light emitting device of claim 5, wherein the oxide is ZnO and ranges from 10 wt % to 25 wt % of the composite oxide layer.

9. The light emitting device of claim 5, wherein the sulfide phosphor has a general formula of (Ca, Sr)S:Eu.

10. A light emitting device, comprising:
a light emitting diode; and
a sulfide phosphor coated with a composite oxide layer, the sulfide phosphor to convert light emitted from the light emitting diode to a different wavelength,
wherein the composite oxide layer comprises a silicon oxide and an oxide of an element selected from the group consisting of B, Ti, and Zn, the oxide being different than the silicon oxide.

11. The light emitting device of claim 10, further comprising a phosphor disposed on the light emitting diode to convert light emitted from the light emitting diode to a wavelength range from 500 nm to 600 nm, wherein the sulfide phosphor has a general formula of (Ca, Sr)S:Eu.

12. The light emitting diode of claim 10, wherein the oxide is B₂O₃.

13. The light emitting diode of claim 10, wherein the oxide is TiO₂.

14. The light emitting diode of claim 10, wherein the oxide ZnO.

15. The light emitting diode of claim 12, wherein B₂O₃ ranges from 5 wt % to 10 wt % of the composite oxide layer.

16. The light emitting device of the claim 13, wherein TiO₂ ranges from 10 wt % to 40 wt % of the composite oxide layer.

17. The light emitting device of claim 14, wherein ZnO ranges from 10 wt % to 25 wt % of the composite oxide layer.

18. The light emitting device of the claim 10, wherein the composite oxide layer is 3 wt % of the sulfide phosphor.

19. A light emitting device, comprising:
a light emitting diode; and
a sulfide phosphor having a general formula of (Ca, Sr)S:Eu, the sulfide phosphor to convert light emitted from the light emitting diode to a different wavelength; and
a composite oxide layer coating the sulfide phosphor,
wherein the composite oxide layer comprises a silicon oxide and an oxide of an element selected from the group consisting of B, Ti, and Zn, the oxide being different than the silicon oxide.

20. The light emitting device of claim 19, wherein the light emitting diode emits light ranging from 290 nm to 420 nm, and the composite oxide layer is 3 wt % of the sulfide phosphor.
